(19) United States
(12) Patent Application Publication
(10) Pub. No.: US 2026/0040885 A1
(43) Pub. Date: Feb. 5, 2026

(54) COMPACT ANCHOR

(71) Applicant: VueReal Inc., Waterloo (CA)

(72) Inventor: Gholamreza CHAJI, Kitchener (CA)

(73) Assignee: VueReal Inc., Waterloo, ON (CA)

(21) Appl. No.: 18/996,019

(22) PCT Filed: Aug. 1, 2024
(86) PCT No.: PCT/CA2024/051018

§ 371 Date: Jan. 17, 2025

Related U.S. Application Data
(60) Provisional application No. 63/516,976, filed on Aug. 1, 2023.
(60) Provisional application No. 63/588,881, filed on Oct. 9, 2023.

(51) Int. Cl. H01L 21/683

(52) U.S. Cl. CPC H01L 21/6835; H01L 2221/68354; H01L 2221/68363; H01L 2221/68381

(57) ABSTRACT

The present disclosure relates to methods of holding microdevices to the cartridge or donor substrate. Here an anchor layer and a release layer are on the donor substrate and the release layer is removed and a free standing anchor layer holds the microdevice. The present invention further relates to the process of microdevice transfer by reducing a bonding force by reducing the release layer area under the microdevice. Here etching and a blocking structure to control the etching rate may be used.

### FIELD OF THE INVENTION

The present disclosure relates to methods of holding microdevices to the cartridge or donor substrate. It also relates to the process of microdevice transfer.

### BRIEF SUMMARY

The present invention relates to a method of holding microdevices to a donor substrate, the method comprising, having an anchor layer and a release on a donor substrate; having a microdevice attached to the anchor layer; having a bonding layer between the microdevice and the anchor layer and having at least one opening in the release layer exposing the donor substrate at a bottom of the opening.

The present invention relates to method to transfer microdevices, the method comprising, coupling microdevices to a donor substrate through a release layer, reducing a release layer area under the microdevice by isotropic etching to reduce a bonding force, and using a blocking structure to control an etching rate from different locations under the microdevice.

### BRIEF DESCRIPTION OF THE DRAWINGS

The foregoing and other advantages of the disclosure will become apparent upon reading the following detailed description and upon reference to the drawings.

FIG. 1A shows an anchor structure on a substrate.

FIG. 1B shows the release layer removed.

FIG. 2A shows an embodiment where microdevices are coupled to a donor substrate through a release layer.

FIG. 2B shows the release layer area under the microdevice 100 can be reduced.

FIG. 3A shows blocking structure is added to control the etching rate from different locations.

FIG. 3B shows the effect of an exemplary blocking layer.

FIG. 3C shows some areas will have a small-area release layer left under microdevices.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

One method of holding microdevices to the cartridge or donor substrate is anchors. The challenge with this approach is that the anchor takes space between the devices, affecting the device pitch.

This invention describes an anchor structure that can perfectly sit under the device and eliminate the need for space between the device for anchor structure.

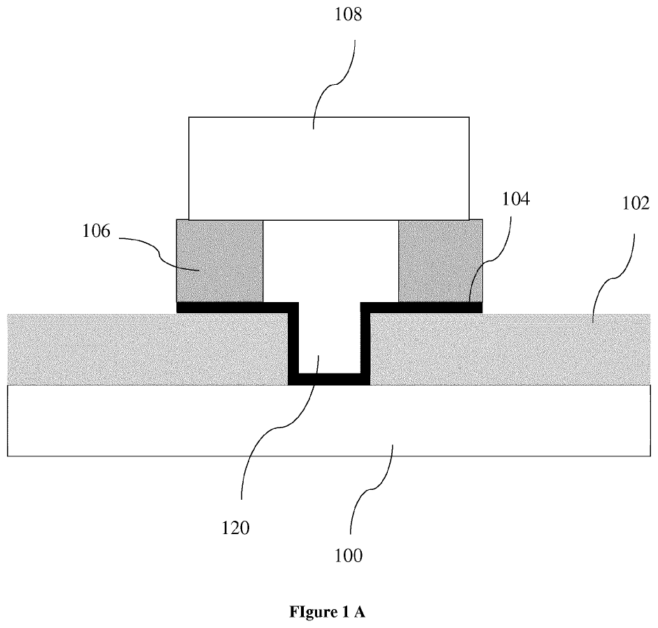

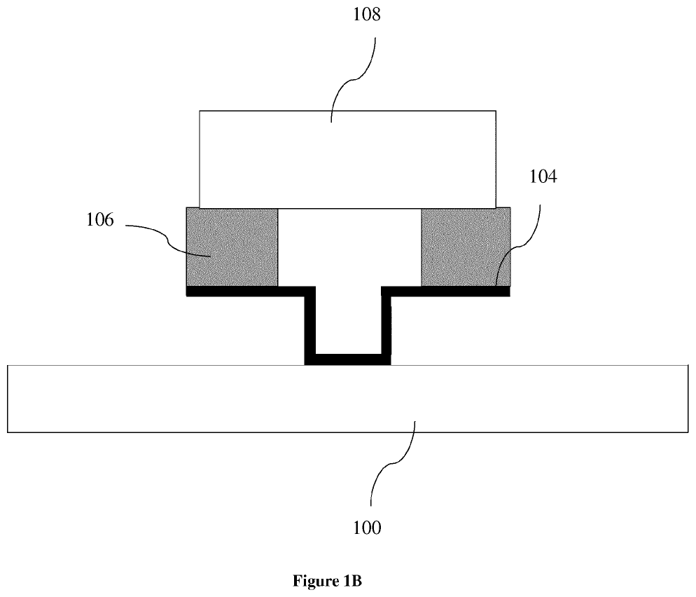

FIG. 1A shows an anchor structure on a donor substrate 100. There is a release layer (or layers) 102 and anchor layer (or layers) 104. And the microdevice device 108 is attached to the anchor layer 104. There can be a bonding layer 106 between the microdevice 108 and the anchor 104. There is at least one opening 120 in the release layer exposing the substrate (or a buffer layer on the substrate) at the bottom of the opening. In one related embodiment, the opening is underneath the device. In another related embodiment the opening has overlap with the microdevice. The anchor layer 104 covers at least part of the opening wall and bottom and connects with the substrate (or the buffer layer(s) on the substrate) at the bottom of the opening. In one related embodiment, the bonding layer is formed on the anchor layer and does not cover the opening. The microdevice is bonded to the anchor structure after the alignment. Here a cavity is formed in the opening.

In another related embodiment, the bonding layer is formed on the device and then the device is bonded to the anchor structure after alignment. Here the bonding layer may have an overlap with the opening.

After the structure is formed and the device is bonded to the anchor structure, the release layer is removed (FIG. 1B) and a free standing anchor layer that includes a wall surface is bonded to the substrate at the opening and is left holding the device in place at the substrate.

The release and anchor layer can be metal, polymer, dielectric or semiconductor. The bonding layer can be polymer, metals or other types of adhesive.

A transfer method is to have an array of microdevices into a donor substrate, and a set of selected microdevices are bonded to a system substrate. The selected microdevices are disconnected from the donor substrate through the bonding process (temperature or pressure) or the donor substrate's separation from the system substrate. To release the microdevices, the bonding structure of microdevices to the donor substrate should either deform enough under bonding or release the microdevices by stronger bonding force during the separation of the donor and system substrates.

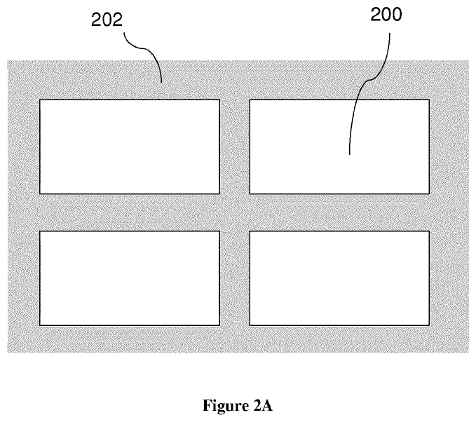

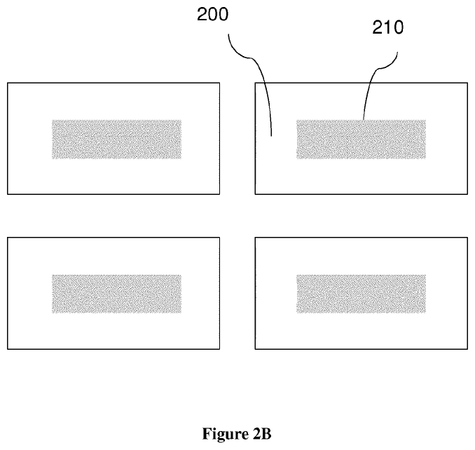

FIG. 2A shows an embodiment where microdevices 200 are coupled to a donor substrate through a release layer 202. The release layer 202 can be a polymer, a metal, a semiconductor, or a dielectric. The coupling can be strong to prevent the removal of microdevices from the donor substrate during the transfer process.

The release layer area 210 under the microdevice 200 can be reduced to reduce the bonding force, as demonstrated in FIG. 2B. The release layer is etched to reduce the area in one related embodiment. The etching can be a wet etch or a dry etch. The etching process of the release layer is isotropic, which means it will etch the layer similarly from all exposed areas. The etch time and etching conditions can be adjusted to control the size of the remaining release layer 210 holding the microdevices 200. In one related case, the etching can be oxygen plasma if the polymer is used as a release layer.

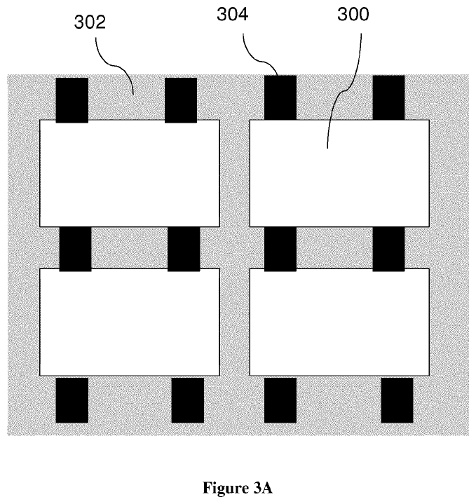

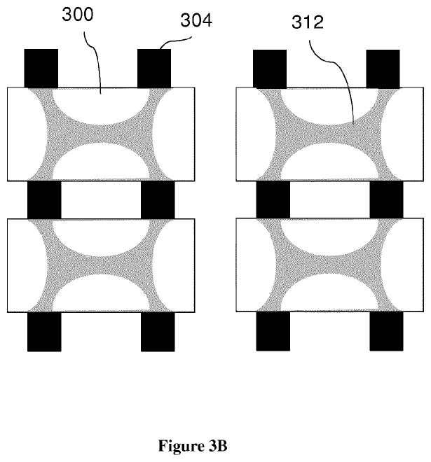

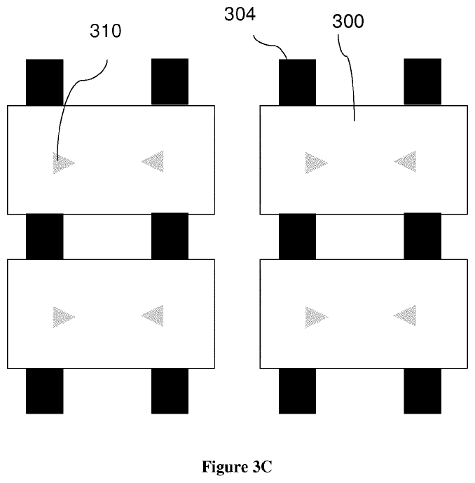

The challenge with etching is that the release layer's location, size and shape under the microdevice 300 is hard to control. In a related embodiment, blocking structure 304 is added to control the etching rate from different locations, as demonstrated in FIG. 3A. The blocking structure 304 can be photoresist, another polymer, dielectric, metal or other material. The blocking structure 304 can enable the control of the place and shape of the remaining release layer 300.

FIG. 3B shows the effect of an exemplary blocking layer 304. As seen during the etching process, the etch rate of the release layer 312 differs around the blocking layer 304. As the etching progresses, some areas will have a small-area release layer 310 left under microdevices 300 as demonstrated in FIG. 3C.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method of holding microdevices to a donor substrate, the method comprising:
having an anchor layer and a release layer on a donor substrate;
having a microdevice attached to the anchor layer;
having a bonding layer between the microdevice and the anchor layer; and
having at least one opening in the release layer exposing the donor substrate at a bottom of the opening.

2. The method of claim 1, wherein the opening is underneath the microdevice.

3. The method of claim 1, wherein the opening has an overlap with the microdevice.

4. The method of claim 1, wherein the anchor layer covers at least part of an opening wall and bottom of the opening and connects with the donor substrate at the bottom of the opening.

5. The method of claim 4, wherein the bonding layer is formed on the anchor layer and does not cover the opening.

6. The method of claim 5, wherein the microdevice is bonded to the anchor layer after an alignment and a cavity is formed in the opening.

7. The method of claim 4, wherein the bonding layer is formed on the microdevice and the microdevice is bonded to the anchor layer after the alignment wherein further the bonding layer has an overlap with the opening.

8. The method of claim 5 or 7, wherein after a structure is formed and the microdevice is bonded to the anchor layer, the release layer is removed and a free standing anchor layer that includes a wall surface is bonded to the donor substrate at the opening and is left holding the microdevice in place at the donor substrate.

9. The method of claim 1, wherein the release and anchor layers comprise of a metal, a polymer, a dielectric or a semiconductor wherein the bonding layer is a polymer, a metal or an adhesive.

10. (canceled)

11. (canceled)

12. (canceled)

13. (canceled)

14. (canceled)

15. (canceled)

16. (canceled)
